(19) United States
(12) Patent Application Publication
(10) Pub. No.: US 2016/0327257 A1
(43) Pub. Date: Nov. 10, 2016

(54) LED POWER SHELL, LED POWER SUPPLY AND LIGHTING DEVICE

(71) Applicant: Shenzhen Ledfriend Optoelectronics Co., Ltd., Shenzhen (CN)

(72) Inventors: Shaoke LI, Shenzhen (CN); Jungao ZHU, Shenzhen (CN); Jianglong LIU, Shenzhen (CN)

(21) Appl. No.: 15/147,649

(22) Filed: May 5, 2016

(30) Foreign Application Priority Data
May 8, 2015 (CN) 201520300330.2

(51) Int. Cl. F21V 23/02; H05K 5/00

(52) U.S. Cl. CPC F21V 23/023; H05K 5/0008; F21Y 2101/02

(57) ABSTRACT

The present invention discloses an LED power shell, including a shell body integrally formed by a metal material, a power surface cover for sealing and covering the shell, and a terminal surface shell, wherein the power surface shell is provided with a baffle downwards bending into a bottom shell, the baffle divides the shell into a power cavity and a terminal cavity, the other three sides of the power surface shell are respectively provided with a bent edge matched with the shell, the periphery of the terminal surface shell is respectively provided with a bent edge matched with the shell, and the shell is connected with the power surface shell and the terminal surface shell through a clamping device. The LED shell according to the present invention has simple structure, is convenient to dismount, has low cost, and satisfies the diversified demands of customers.

### CROSS-REFERENCE TO RELATED APPLICATIONS

This application claims the benefit of Chinese application Serial No.

201520300330.2, filed May 8, 2015, the disclosure of which is incorporated by reference herein in its entirety.

### TECHNICAL FIELD

The present invention relates to the field of lighting technologies, and more particularly, to an LED power shell, an LED power supply installing the same, and a lighting device.

### BACKGROUND ART

LED as energy for energy-saving and environmental protection, has been widely used in various occasions, especially a panel light has been widely applied to indoor lighting; therefore, each region has a very strict safety requirement on it. On the basis of safety, the United States unifies the standard for using flat light power connectors. In order to reach the standard required above, all the power shells sold in the market at present employ a metal plate shell, with a plastic shell putted inside, and two ends for wire incoming and outgoing, wherein the left end is used for incoming while the right for outgoing. The foregoing power shell has the following defects: (1) simultaneous incoming/outgoing of diversified connectors cannot be satisfied, so that the selection range offered to the customers is small; (2) one plastic shell is additionally arranged inside the metal shell, causing poor heat dissipation performances of the power supply, so that the service life of the power supply and the service life of the lighting device are affected; (3) placing the two shells together is not beneficial for large-scale production, and decreases the competitiveness; and (4) one power supply uses two shells, which causes a high system cost.

### SUMMARY OF THE INVENTION

The object of the present invention is to solve the foregoing problems of the prior art, and provide an LED power shell which has the advantages of simple structure, simple assembly, low cost and good heat dissipation effects, is tightly buckled, and satisfy the safety requirement.

The invention employs the following technical solution.

An LED power shell includes a shell body integrally formed by a metal material, a power surface cover for sealing and covering the shell, and a terminal surface shell, wherein the power surface shell is provided with a baffle downwards bending into a bottom shell, the baffle divides the shell into a power cavity and a terminal cavity, the other three sides of the power surface shell are respectively provided with a bent edge matched with the shell, the periphery of the terminal surface shell is respectively provided with a bent edge matched with the shell, and the shell is connected with the power surface shell and the terminal surface shell through a clamping device.

The inner wall of the power cavity of the shell is provided with an insulating sheet.

The front side surface and the left and right side surfaces of the terminal cavity are respectively provided with a knock-off hole for perforating leads.

The bottom of the shell is provided with fixing holes for fixing the shell, screw pillars for fixing an LED power board, a binding post and an outgoing hole, and both the binding post and the outgoing hole are located in front of the terminal cavity of the shell.

The clamping device includes a pair of rectangle clamping grooves respectively arranged on the left and right side surfaces of the shell as well as a pair of rectangle clamping buckles arranged on the bent edge of the power surface shell and matched with the rectangle clamping grooves.

A male connector is arranged between the rectangle clamping grooves of the shell, and a female slot matched with the male connector is arranged on the bent edge of the power surface shell.

The clamping device further includes a pair of circular clamping holes respectively arranged on the left and right side surfaces of the shell as well as a pair of circular clamping buckles arranged on the bent edges of the left and right side surfaces of the terminal surface shell and matched with the circular clamping holes; two screw holes, one screw hole being arranged on a convex plate which internally protrudes out from the middle of the top of the front side surface of the terminal cavity while the other being arranged on the terminal surface shell, and a connection screw.

The present invention also provides an LED power supply using the foregoing LED power shell. The present invention also provides a lighting device having the foregoing LED power shell.

Compared with the prior art, the present invention has the advantageous effects.

1. The power shell according to the present invention cancels the internal plastic shell, shortens the assembly time during production, and saves the cost.

2. The present invention is designed with diversified incoming/outgoing holes, which can be connected in parallel or in series for the customers to use, thus satisfying the diversified demands of the customer.

3. By cancelling the plastic shell and optimizing the shell structure, the power supply according to the present invention has better heat dissipation performances, so that the efficiency thereof is increased and the service life thereof is prolonged.

### BRIEF DESCRIPTION OF THE DRAWINGS

FIG. 1 is an exploded drawing of an LED power shell according to the present invention;

FIG. 2 is a stereoscopic schematic diagram of a shell according to the present invention;

FIG. 3 is a schematic diagram of a section along B-B line in FIG. 2;

FIG. 4 is a stereoscopic diagram of the shell according to the present invention; and

FIG. 5 is a block diagram of an RFID-based pre-sales/after-sales information collection and analysis system according to the present invention.

### DETAILED DESCRIPTION OF THE PREFERRED EMBODIMENTS

In order to make the objects, technical solutions and advantages of the present invention more clear, the present invention will be further described in details hereinafter with reference to the drawings and embodiments. It should be understood that the specific embodiments described herein are only for explanation of the present invention only, but are not intended to limit the protection scope of the present invention.

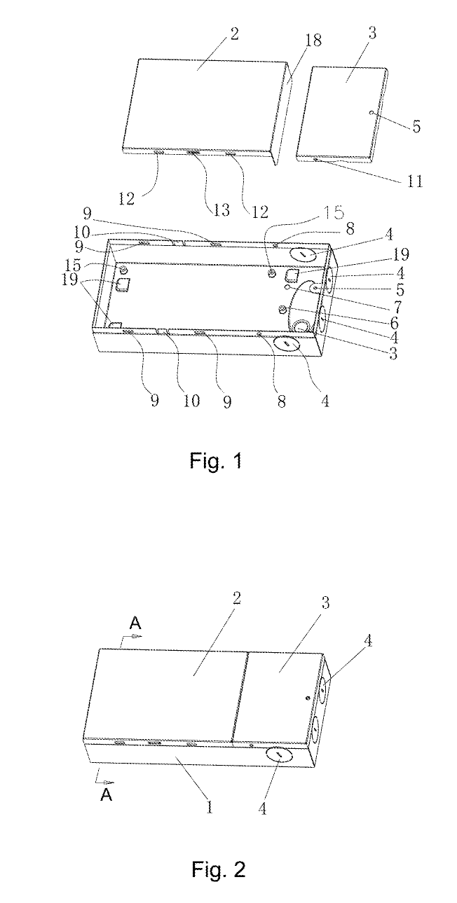

As shown in FIG. 1 and FIG. 2, the LED power shell provided by the present invention is composed of a shell 1 that is integrally formed, and a power surface cover 2 for covering the shell and a terminal surface shell 3. One side of the power surface cover 2 is provided with a baffle 18 downwards bending into a bottom shell, the baffle divides the shell into a power cavity and a terminal cavity, and the other three sides of the power surface shell are respectively provided with a bent edge matched with the shell. The periphery of the terminal surface shell is respectively provided with a bent edge matched with the shell, and the shell is connected with the power surface shell and the terminal surface shell through a clamping device

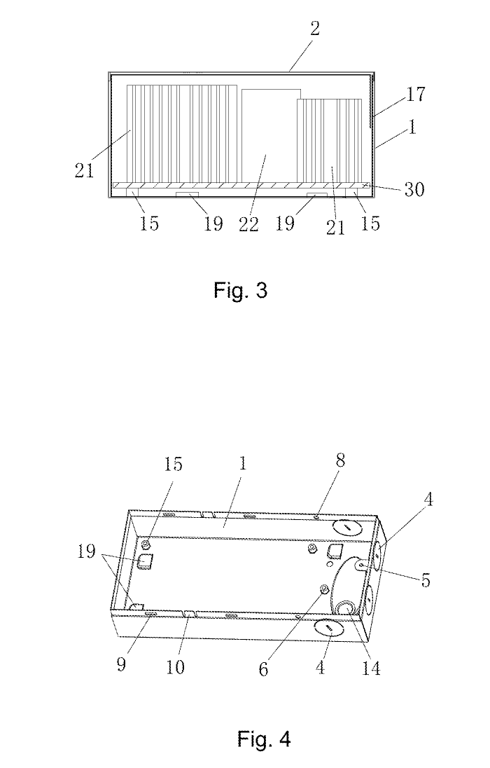

As shown in FIG. 1 and FIG. 4, the LED power shell is provided with: four screw pillars 15 distributed at the bottom of the shell and configured to support and fix an LED driving power circuit board 30 (as shown in FIG. 3) in the shell; an outgoing hole 14 located at the front end of the bottom surface of the terminal cavity of the shell and only configured to perforate output wires; four knock-off holes 4, wherein two are located on the front side surface of the shell and the other two are respectively located on the left side and right side of the shell for perforating input wires or output wires, and a user may select to open one or more knock-off holes according to demands freely; two screw holes 5, wherein one is located on a convex plate which internally protrudes out from the middle of the top of the front side of the terminal cavity while the other is arranged on the terminal surface shell 3 and fixes the terminal surface shell and the shell through screws; a binding post 6 located on the bottom surface of the front end of the shell and only configured to connect an electric wire; two circular clamping holes 8 respectively arranged at the left and right side surfaces of the shell and matched with circular clamping buckles 11 arranged on the bent edge of the terminal surface shell 3 to fix the shell and the terminal surface shell; four rectangle clamping grooves 9 located at the left and right sides of the rear portion of the shell and matched with the rectangle clamping buckles 12 on the power surface cover to fix the shell and the power surface cover; and two male connectors 10 respectively arranged at the left and right sides of the shell and located between the rectangle clamping grooves 9, matched and used with female slots 13 arranged on the bent edge of the power surface cover to reinforce the connection between the shell and the power surface cover.

FIG. 2 is a stereoscopic schematic diagram of the present invention. The LED power shell includes a shell 1, a power surface cover 2 and a terminal surface shell 3. The shell 1 is tightly buckled and connected with the power surface cover in a detachable manner through a clamping device, and cannot be easily dismounted; the junction between the front surface of the power surface cover 2 and the terminal surface shell 3 is downwards bent into a baffle for separating an LED driving power electric cavity and a wiring terminal cavity, so as to ensure the safety requirement standard. The terminal surface shell 3 and the shell 1 are connected in a detachable manner through circular clamping buckles and screw threads for sealing and covering the portion of the LED power terminal.

FIG. 3 is a schematic diagram showing a cross section of the power cavity. The inner wall of the power cavity is provided with an insulating sheet 17. The insulating sheet is preferably a mylar sheet. The insulating sheet covers the LED driving power. The LED driving power circuit board 30 is installed on the screw pillars 15 through screws. A radiator 21 and a transformer 22 are installed on the circuit board 30.

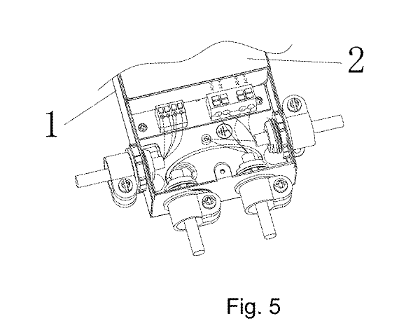

FIG. 5 is a wiring schematic diagram of the terminal portion. In the embodiment, four knock-off holes are all opened. During actual application, one or more knock-off holes can be opened according to requirements.

The LED power shell provided by the present invention includes the power cavity for installing electrical members and the terminal cavity for installing connecting members, wherein safety requirement protection shall be made for the former cavity served as the assembly position of the power supply; therefore, the shell and the power surface cover are buckled and connected through at least a pair of clamping devices, are connected firmly and cannot be easily separated; the connecting cavity is configured for facilitating the connecting operation of the customer when in use; therefore, the shell and the terminal surface shell are buckled and connected in a detachable manner through a pair of clamping devices, and are relatively easier to separate.

What is claimed is:

1. An LED power shell, comprising a shell body integrally formed by a metal material, a power surface cover for sealing and covering the shell, and a terminal surface shell, wherein the power surface shell is provided with a baffle downwards bending into a bottom shell, the baffle divides the shell into a power cavity and a terminal cavity, the other three sides of the power surface shell are respectively provided with a bent edge matched with the shell, the periphery of the terminal surface shell is respectively provided with a bent edge matched with the shell, and the shell is connected with the power surface shell and the terminal surface shell through a clamping device.

2. The LED power shell according to claim 1, wherein the inner wall of the power cavity of the shell is provided with an insulating sheet.

3. The LED power shell according to claim 1, wherein the front side surface and the left and right side surfaces of the terminal cavity are respectively provided with a knock-off hole for perforating leads.

4. The LED power shell according to claim 1, wherein the bottom of the shell is provided with fixing holes for fixing the shell, screw pillars for fixing an LED power board, a binding post and an outgoing hole, and both the binding post and the outgoing hole are located in front of the terminal cavity of the shell.

5. The LED power shell according to claim 1, wherein the clamping device includes a pair of rectangle clamping grooves respectively arranged on the left and right side surfaces of the shell as well as a pair of rectangle clamping buckles arranged on the bent edge of the power surface shell and matched with the rectangle clamping grooves.

6. The LED power shell according to claim 5, wherein a male connector is arranged between the rectangle clamping grooves of the shell, and a female slot matched with the male connector is arranged on the bent edge of the power surface shell.

7. The LED power shell according to claim 1, wherein the clamping device includes a pair of circular clamping holes respectively arranged on the left and right side surfaces of the shell as well as a pair of circular clamping buckles arranged on the bent edges of the left and right sides of the terminal surface shell and matched with the circular clamping holes; two screw holes, one screw hole being arranged on a convex plate which internally protrudes out from the middle of the top of the front side surface of the terminal cavity while the other being arranged on the terminal surface shell, and a connection screw.

8. An LED power supply using the LED power shell according to claim 1.

9. A lighting device having the LED power supply according to claim 8.
